(19) United States
(12) Patent Application Publication
(10) Pub. No.: US 2017/0077431 A1
(43) Pub. Date: Mar. 16, 2017

(54) ORGANIC PHOTOELECTRIC CONVERSION DEVICE

(71) Applicant: Kabushiki Kaisha Toshiba, Minato-ku (JP)

(72) Inventors: Yukitami MIZUNO, Ota (JP); Isao TAKASU, Setagaya (JP); Atsushi WADA, Kawasaki (JP)

(73) Assignee: Kabushiki Kaisha Toshiba, Minato-ku (JP)

(21) Appl. No.: 15/259,536

(22) Filed: Sep. 8, 2016

(30) Foreign Application Priority Data
Sep. 10, 2015 (JP) 2015-178117

(51) Int. Cl. H01L 51/42; H01L 27/30

(52) U.S. Cl. CPC H01L 51/4273; H01L 27/307; H01L 2251/303; H01L 51/0061

(57) ABSTRACT

According to one embodiment, an organic photoelectric conversion device includes: an organic photoelectric conversion layer, a metal-oxide layer, and a buffer layer. The metal-oxide layer includes metal oxide. The buffer layer is provided between the organic photoelectric conversion layer and the metal-oxide layer. The buffer layer includes a material having a property of blocking an exciton, and a glass transition temperature of the material is higher than or equal to 415K.

### CROSS-REFERENCE TO RELATED APPLICATION

This application is based upon and claims the benefit of priority from Japanese Patent Application No. 2015-178117, filed Sep. 10, 2015; the entire contents of which are incorporated herein by reference.

### FIELD

Embodiments described herein relate generally to an organic photoelectric conversion device.

### BACKGROUND

An organic photoelectric conversion device includes an organic photoelectric conversion layer and is used in, for example, a solar cell.

In photovoltaic power generation using solar cells, light energy is directly converted into electric power by use of an organic photoelectric conversion device utilizing a photovoltaic effect.

Solid-state image sensing devices are widely used in various fields in, for example, digital cameras, mobile terminals such as portable telephones (including smartphones), monitoring cameras, web cameras utilizing the internet, and the like.

Among such solid-state image sensing devices, a sensor is known which has an organic photoelectric converter that carries out photoelectric conversion by an organic photoelectric conversion layer.

In the organic photoelectric conversion device and the solid-state image sensing device which are described above, it is of importance to improve photoelectric conversion efficiency in the organic photoelectric conversion layer. Therefore, the configuration of the aforementioned organic photoelectric conversion device or the materials used to form layers constituting the aforementioned organic photoelectric conversion device has been studied.

However, it may be difficult to improve the photoelectric conversion efficiency of the organic photoelectric conversion layer depending on the layered structures of the organic photoelectric conversion device and the solid-state image sensing device.

### BRIEF DESCRIPTION OF THE DRAWINGS

FIG. 1 is a cross-sectional view showing an organic photoelectric conversion device according to a first embodiment.

FIG. 2 is a cross-sectional view showing a main part of a solid-state image sensing device according to a second embodiment.

FIG. 3 is a perspective view showing an example of a CMOS image sensor to which the solid-state image sensing device according to the second embodiment is applied.

FIG. 4 is a perspective view showing another example of a CMOS image sensor to which the solid-state image sensing device according to the second embodiment is applied.

FIG. 5 is a plan view showing a smartphone serving as an imaging device provided with a CMOS image sensor built therein.

FIG. 6 is a plan view showing a tablet terminal device serving as an imaging device provided with a CMOS image sensor built therein.

FIG. 7 is a plan view showing an example of an automobile provided with a car-mounted camera and an on-board image display device.

FIG. 8 is a plan view showing another example of an automobile provided with a car-mounted camera and an on-board image display device.

### DETAILED DESCRIPTION

Hereinafter, an organic photoelectric conversion device and a solid-state image sensing device according to the embodiment will be described with reference to drawings.

According to one embodiment, an organic photoelectric conversion device includes: an organic photoelectric conversion layer, a metal-oxide layer, and a buffer layer. The metal-oxide layer includes metal oxide. The buffer layer is provided between the organic photoelectric conversion layer and the metal-oxide layer. The buffer layer includes a material having a property of blocking an exciton, and a glass transition temperature of the material is higher than or equal to 415K.

### First Embodiment

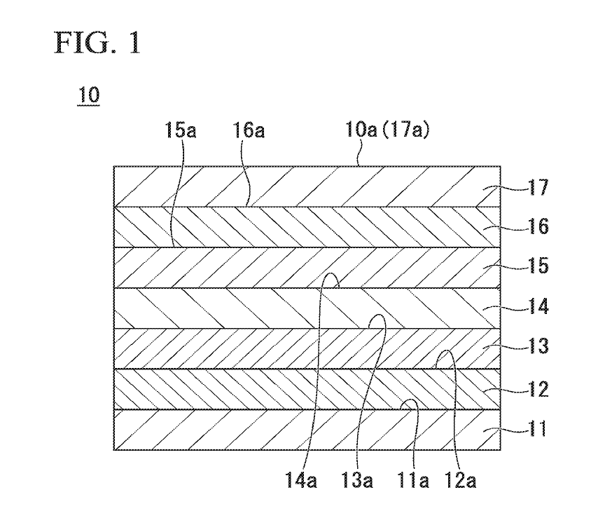

FIG. 1 is a cross-sectional view showing an organic photoelectric conversion device according to a first embodiment.

As shown in FIG. 1, the organic photoelectric conversion device 10 according to the first embodiment is an inverted structure device. In the configuration of the organic photoelectric conversion device 10, a substrate 11, a negative electrode 12, a positive-hole blocking layer 13, an organic photoelectric conversion layer 14, a buffer layer 15, a metal-oxide layer 16, and a positive electrode 17 are stacked in order.

The substrate 11 has a flat top surface 11a.

For example, a substrate having optical transparency (e.g., glass substrate), a substrate that does not allow light to be transmitted therethrough (e.g., a multi-layer wiring substrate including a circuit), or the like can be used as the substrate 11.

The negative electrode 12 is an electrode functioning as a lower electrode and is provided so as to cover the top surface 11a of the substrate 11.

The negative electrode 12 arranged so as to face the positive electrode 17 with the positive-hole blocking layer 13, the organic photoelectric conversion layer 14, the buffer layer 15, and the metal-oxide layer 16 interposed therebetween.

The negative electrode 12 is in contact with the positive-hole blocking layer 13.

The material used to form the negative electrode 12 can be selected in consideration of adhesion between the negative electrode 12 and the organic photoelectric conversion layer 14, the energy level, stability, or the like. For example, a metal, an alloy, a metal oxide, an electroconductive compound, a composite of these materials, or the like can be used as the material of the negative electrode 12; however, the material is not limited to this.

As a specific material used to form the negative electrode 12, for example, indium tin oxide (ITO), SnO₂ to which a dopant is added, aluminum zinc oxide (AZO) in which Al serving as a dopant is added to ZnO, gallium zinc oxide (GZO) in which Ga serving as a dopant is added to ZnO, indium zinc oxide (IZO) in which In serving as a dopant is added to ZnO, or the like can be used.

As a material used to form the negative electrode 12, for example, CdO, TiO₂, CdIn₂O₄, InSbO₄, Cd₂SnO₂, Zn₂SnO₄, MgInO₄, CaGaO₄, TiN, ZrN, HfN, LaB₆, or the like may be used.

As a material used to form the negative electrode 12, for example, an electroconductive high-polymer (for example, PEDOT:PSS, polythiophene compound, polyaniline compound, or the like) may be used.

As a material used to form the negative electrode 12, for example, nano-carbon based materials such as a carbon nanotube or graphene, Ag nano-wire, or the like can be used.

In the case where the negative electrode 12 is not required to have optical transparency, a metal material such as W, Ti, TiN, or Al can be used as a material used to form the negative electrode 12.

The aforementioned negative electrode 12 can be formed by a well-known method.

The positive-hole blocking layer 13 is provided so as to cover a top surface 12a (surface located near the positive electrode 17) of the negative electrode 12.

The positive-hole blocking layer 13 is arranged between the negative electrode 12 and the organic photoelectric conversion layer 14.

The positive-hole blocking layer 13 is a layer used to block the holes generated from the negative electrode 12 from transferring to the organic photoelectric conversion layer 14.

As a result of providing the positive-hole blocking layer 13 between the negative electrode 12 and the organic photoelectric conversion layer 14 as mentioned above, it is possible to prevent the holes from being injected from the negative electrode 12 to the organic photoelectric conversion layer 14 while lowering a work function.

As a material used to form the positive-hole blocking layer 13, for example, Polyethylenimine Ethoxylated (hereinbelow, referred to as “PEIE”), Polyethylenimine (PEI), Poly (acrylamide) (PAAm), Poly ((9, 9-bis (3′-(N,N dimethylamino) propyl)-2, 7-fluorene)-alt-2, 7-(9, 9-dioctylfluorene) (PFN), or the like can be used.

The organic photoelectric conversion layer 14 is provided so as to cover a top surface 13a (surface located near the positive electrode 17) of the positive-hole blocking layer 13.

The organic photoelectric conversion layer 14 photoelectrically converts the light received by the organic photoelectric conversion layer 14 into power through a light-receiving face 10a of the organic photoelectric conversion device 10 (in other words, a top surface 17a of the positive electrode 17).

In the case of using the organic photoelectric conversion device 10 as a constituent element of a solar cell, for example, a P-type semiconductor single layer, an N-type semiconductor single layer, a layered structure of a P-type semiconductor layer and an N-type semiconductor layer, a mixed film formed by application of a P-type semiconductor and an N-type semiconductor while mixing the semiconductors, a mixed film formed by codeposition of a P-type semiconductor and an N-type semiconductor, or the like can be used as the organic photoelectric conversion layer 14.

As the P-type semiconductor, for example, a P-type organic semiconductor can be used.

As the N-type semiconductor, for example, an N-type organic semiconductor can be used.

As the P-type organic semiconductor and the N-type organic semiconductor, for example, amine derivatives, quinacridone derivatives, naphthalene derivatives, anthracene derivatives, phenanthrene derivatives, tetracene derivatives, pyrene derivatives, perylene derivatives, and fluoranthene derivatives, or the like can be used.

A polymer such as phenylene vinylene, florene, carbazole, indole, pyrene, pyrrole, picoline, thiophene, acetylene, diacetylene, or derivatives of these materials can be used as the P-type organic semiconductor and the N-type organic semiconductor.

As the P-type organic semiconductor and the N-type organic semiconductor, for example: a condensation polynuclear aromatic compound and a chain compound in which an aromatic ring compound or a heterocyclic compound is condensed, such as dithiol metal complex-based pigments, a metal phthalocyanine pigment, a metal porphyrin pigment, a ruthenium complex pigment, cyanine-based pigments, merocyanine-based pigments, phenyl xanthene-based pigments, triphenyl methane-based pigments, rhodacyanine-based pigments, xanthene-based pigments, macrocyclic azaannulene-based pigments, azulene-based pigments, naphthoquinone, anthraquinone-based pigments, anthracene, or pyrene; two nitrogen heterocycles such as quinoline having a squarylium group and a croconic methine group as a bonded chain, benzothiazole, or benzoxazole; a pigment similar to cyanine series bonded by a squarylium group and a croconic methine group; or the like can be used.

As the N-type semiconductor, fullerene such as C60 or C70, and a derivative thereof can be used.

In consideration of the photoelectric conversion efficiency, the organic photoelectric conversion layer 14 is preferably a mixed film of, for example, a P-type semiconductor and an N-type semiconductor.

In this case, it is preferable to use a derivative including, for example, amine, quinacridone, thiophene, carbazole, or the like, or a polymer of these materials as the P-type semiconductor.

It is preferable to use, for example, perylene derivatives, naphthalene derivatives, thiophene derivatives, or fullerene derivatives as the N-type semiconductor.

In the case of using the organic photoelectric conversion device 10 as a solar cell, the thickness of the organic photoelectric conversion layer 14 can be properly determined to be in the range of, for example, 30 to 300 nm.

In the case where the thickness of the organic photoelectric conversion layer 14 is smaller than 30 nm, there is a possibility that it is difficult to sufficiently ensure the photoelectric conversion efficiency of the organic photoelectric conversion layer 14.

On the other hand, in the case where the thickness of the organic photoelectric conversion layer 14 is greater than 300 nm, there is a possibility that the voltage to be applied to the organic photoelectric conversion layer 14 becomes higher, and therefore there is a concern that it is not suitable for reducing power consumption.

Each of layers constituting the organic photoelectric conversion layer 14 can be formed by, for example, a dry film-forming method or a wet film-forming method.

As the dry film-forming method, for example: physical vapor deposition methods such as a vacuum deposition method, a sputtering method, an ion plating method, or a molecular beam epitaxy method (MBE: Molecular Beam Epitaxy); or a chemical vapor deposition method (CVD method) such as plasma polymerization can be used.

As the wet film-forming method, for example, coating methods such as a cast method, a spin coating method, a dipping method, a LB method can be used.

Each of layers constituting the organic photoelectric conversion layer 14 may be formed by printing methods such as an inkjet printing method or a screen printing method, or transfer methods such as a thermal transfer method or a laser transfer method.

In the case of using a high-molecular compound as an organic semiconductor material included in the organic photoelectric conversion layer 14, in consideration of ease of manufacture thereof, it is preferable to use methods such as a wet film-forming method, a printing method, or a transfer method.

On the other hand, in the case of using a low-molecular compound as an organic semiconductor material included in the organic photoelectric conversion layer 14, it is preferable to use a dry film-forming method, particularly, a vacuum deposition method is more preferable.

In the case of using the vacuum deposition method, in consideration of carrying out uniform vapor deposition, it is preferable to carry out the vapor deposition while rotating a substrate 32.

The buffer layer 15 is provided so as to cover a top surface 14a (surface located near the positive electrode 17) of the organic photoelectric conversion layer 14.

The buffer layer 15 is arranged between the organic photoelectric conversion layer 14 and the metal-oxide layer 16.

The buffer layer 15 includes a material having a glass transition temperature of 415K or more and having a property of blocking an exciton.

Here, “property of blocking an exciton” means the characteristics that the terminal wavelength of the fluorescence spectrum of the short-wavelength side of the organic photoelectric conversion layer 14 is longer than the terminal wavelength of the long-wavelength side of the buffer layer 15 functioning as an exciton blocking layer.

As a material which is the material used to form the buffer layer 15, has a glass transition temperature of 415K or more, and has a property of blocking an exciton, for example, derivatives and polymers including triphenyl amine are preferably used. Specifically, it is preferable to use, for example, 4, 4′, 4″-Tri (9-carbazoyl) triphenylamine (hereinbelow, referred to as “TCTA”).

TCTA is the material which has a glass transition temperature of 424K, and in which a crucible temperature during vapor deposition of TCTA is 289° C., the absorption terminal wavelength of the long-wavelength side is 420 nm, the hole mobility of TCTA is 2×10⁻⁴ cm²/Vs, the HOMO level is 5.7 eV, and the LUMO level is 2.4 eV.

As described above, as a result of providing the buffer layer 15 between the organic photoelectric conversion layer 14 and the metal-oxide layer 16 where the buffer layer 15 includes the material having a property of blocking an exciton and a glass transition temperature of the material is greater than or equal to 415K, the excitons generated from the organic photoelectric conversion layer 14 can be prevented from transferring to the metal-oxide layer 16.

That is, the buffer layer 15 can function as an exciton blocking layer.

Consequently, since it is possible to reduce deactivation of the exciton which occurs due to recombination of an electron and a hole in the organic photoelectric conversion layer 14, it is possible to improve the photoelectric conversion efficiency of the organic photoelectric conversion device 10.

Hereinbelow, the reason that the inventors reached the invention and how the inventors found the invention will be described.

In the configuration of the organic photoelectric conversion device 10 which functions as an inverted structure device shown in FIG. 1, it is essential that the metal-oxide layer 16 (for example, a molybdenum oxide layer made of molybdenum oxide which is a wide bandgap material) is arranged above the organic photoelectric conversion layer 14.

For example, in the case of using a molybdenum oxide layer made of molybdenum oxide as the metal-oxide layer 16, generally, the excitons generated from the organic photoelectric conversion layer 14 does not transfer to the molybdenum oxide layer.

However, in the case where the reciprocal action between the organic photoelectric conversion layer 14 and the molybdenum oxide layer occurs, there is a possibility that the energy level appears even at a lower position, in such case, there is a concern that the exciton energy will be transferred to the molybdenum oxide layer.

The inventors discovered how to sandwich the buffer layer 15 between the organic photoelectric conversion layer 14 and the molybdenum oxide layer and thereby prevent the excitation energy from transferring to the molybdenum oxide layer.

As the material used to form the buffer layer 15, it is necessary to use a material having an excitation energy level at the position higher than that of the excitation energy generated in the organic photoelectric conversion layer 14.

In the field of solid-state image sensing devices, it is assumed that, a material that is excited by absorbing visible light is used as a material used to form the organic photoelectric conversion layer 14.

Therefore, the amount of the excitation energy generated in the organic photoelectric conversion layer 14 is the amount of energy generated by the visible light.

Consequently, as a material used to form the buffer layer 15, it is necessary to use a material that hardly absorbs light in a visible light region.

Preliminarily, the inventors carried out experiments and analyzed materials used to form the buffer layer. The inventors found that, it doesn't mean that, any materials may be used as the material used to form the buffer layer 15 in the case where the most amount of light is not absorbed in a visible light region.

Particularly, it was found that, in the case of using a molybdenum oxide layer as the metal-oxide layer 16 in the organic photoelectric conversion device 10 serving as an inverted structure device, in some cases, the photoelectric conversion efficiency of the organic photoelectric conversion device 10 cannot be improved depending on the kinds of materials used to form the buffer layer 15.

The inventors considered the matter described above and focused on the glass transition temperature of the material used to form the buffer layer 15.

The inventors presumed that, when a molybdenum oxide layer is formed, the thermal energy of the molybdenum oxide incoming to the upper of the buffer layer 15 transfers to the constituent material of the buffer layer 15 (it may be conceivable that molybdenum oxide enters the foundation of the buffer layer 15), and therefore the characteristics of the buffer layer 15 may be changed.

It is conceivable that the factors causing the characteristics of the buffer layer 15 to be changed are the following three cases.

First Case: molybdenum oxide is incoming to the buffer layer 15, the thermal energy of the molybdenum oxide transfers to the buffer layer 15, the buffer layer 15 is heated at the temperature higher than or equal to the glass transition temperature and is in a molten state, and when the molten buffer layer 15 is solidified, the state of this molten buffer layer 15 is different from the state where the buffer layer 15 is initially formed or the orientation of this molten buffer layer 15 is different from that of the initially-formed buffer layer 15.

Second Case: molybdenum oxide is incoming to the buffer layer 15, the thermal energy of the molybdenum oxide transfers to the buffer layer 15, the buffer layer 15 is heated at the temperature higher than or equal to the glass transition temperature, and when the buffer layer 15 is in a molten state, the molybdenum oxide is melted into the buffer layer 15.

Third Case: molybdenum oxide is incoming to the buffer layer 15, the thermal energy of the molybdenum oxide transfers to the buffer layer 15, the buffer layer 15 is heated at the temperature higher than or equal to the glass transition temperature, the material of the buffer layer 15 is in motion by thermal agitation or the material of the buffer layer 15 is eliminated in a state of substantially sublimation, and the molybdenum oxide enters the portion at which the material of the buffer layer 15 is eliminated.

Accordingly, the inventors discovered how to select, as a material used to form the buffer layer 15, the material having a glass transition temperature of 415K or more at which the material resists the thermal energy of the metal-oxide layer 16 and having a property of blocking an exciton.

Moreover, the inventors formed the buffer layer 15 by use of the foregoing material, carried out experiments therefor. As a result, it is furthermore observed that the damage due to multilayer deposition of the metal-oxide layer 16 can be reduced while confining the excitation energy in the organic photoelectric conversion layer 14.

That is, it can be determined that it is possible to improve the photoelectric conversion efficiency of the organic photoelectric conversion device 10 while avoiding degradation derived from processes.

As mentioned above, as a result of using the material having a glass transition temperature of 415K or more and having a property of blocking an exciton as the buffer layer 15, thermal stability is improved, the organic photoelectric conversion layer 14 can be prevented from being chemically reacted due to the energy generated when the metal-oxide layer 16 is formed, or the organic photoelectric conversion layer 14 can be prevented from being reacted with the metal-oxide layer 16 (for example, the metal-oxide layer 16 can be prevented from entering the organic photoelectric conversion layer 14).

It is preferable that the buffer layer 15 have a hole transporting property, for example, which is capable of transporting the holes generated in the organic photoelectric conversion layer 14, to the boundary face between the metal-oxide layer 16 and the buffer layer 15.

Since the buffer layer 15 has a hole transporting property which can transport the holes to the boundary face between the metal-oxide layer 16 and the buffer layer 15 as stated above, even in case where the thickness of the buffer layer 15 is large, it is possible to improve the photoelectric conversion efficiency of the organic photoelectric conversion device 10.

The buffer layer 15 can be formed by, for example, a vapor-deposition method.

As the vapor-deposition method, for example, a vacuum deposition method which is one of physical vapor-deposition methods (PVD methods) can be used.

In other cases, the buffer layer 15 may be formed by a method other than the vapor-deposition method, for example, the buffer layer 15 may be formed using an application method.

The absorption terminal wavelength of the buffer layer 15 may be, for example, less than 380 nm.

As a result of determining the absorption terminal wavelength of the buffer layer 15 to be less than 380 nm as stated above, the light to be captured by the organic photoelectric conversion layer 14 can be prevented from being attenuated due to absorption of visible light (wavelength of 380 to 780 nm) by the buffer layer 15.

Consequently, it is possible to prevent the photoelectric conversion efficiency of the organic photoelectric conversion device 10 from being degraded.

For example, the mobility of the holes of the buffer layer 15 may be greater than or equal to the mobility of the holes of the organic photoelectric conversion layer 14.

As mentioned above, as the mobility of the holes of the buffer layer 15 greater than or equal to the mobility of the holes of the organic photoelectric conversion layer 14, the holes generated from the organic photoelectric conversion layer 14 are likely to reach the boundary face between the buffer layer 15 and the metal-oxide layer 16 through the buffer layer 15, and is thereby possible to prevent the photoelectric conversion efficiency of the organic photoelectric conversion device 10 from being degraded.

The thickness of the buffer layer 15 is preferably in the range of, for example, 5 nm to 200 nm.

In the case where the thickness of the buffer layer 15 is less than 5 nm, there is a concern that the effect of relieving the damage of the organic photoelectric conversion layer 14 when the metal-oxide layer 16 is formed will be reduced.

On the other hand, in the case where the thickness of the buffer layer 15 is greater than 200 nm, there is a concern that it is difficult for holes to transfer to the boundary face, and therefore there is a concern that the photoelectric conversion efficiency will be degraded.

Accordingly, as a result of determining the thickness of the buffer layer 15 to be in the range of 5 nm to 200 nm, it is possible to prevent the organic photoelectric conversion layer 14 from being damaged when the metal-oxide layer 16 is formed, and additionally it is possible to prevent the photoelectric conversion efficiency from being degraded.

Particularly, the thickness of the buffer layer 15 is preferably in the range of, for example, 5 nm to 100 nm.

As a result of determining the thickness of the buffer layer 15 to be in the range of 5 nm to 100 nm, it is possible to further prevent the photoelectric conversion efficiency from being degraded.

Regarding the buffer layer 15, the buffer layer 15 may photoelectrically convert light into power by itself and the buffer layer 15 may not photoelectrically convert light into power.

The metal-oxide layer 16 is provided so as to cover a top surface 15a (surface located near the positive electrode 17) of the buffer layer 15.

The metal-oxide layer 16 has a function of inhibiting electrons from being injected from the positive electrode 17 to the organic photoelectric conversion layer 14 when a voltage is applied between the negative electrode 12 and the positive electrode 17 (a function of blocking electrons).

The metal-oxide layer 16 is a layer including a metal oxide.

As metal oxide included in the metal-oxide layer 16, metal oxide including at least one of, for example, molybdenum oxide, vanadium oxide, tungsten oxide, nickel oxide, and rhenium oxide can be used.

As a result of using such metal oxide, it is possible to sufficiently prevent electrons from being injected from the positive electrode 17 to the organic photoelectric conversion layer 14.

It is preferable that the conduction band of the metal oxide be lower, by 0.5 eV or more, than the LUMO level of the material (material included the buffer layer 15) having a property of blocking an exciton and having a glass transition temperature of, for example, greater than or equal to 415K.

In the case where the conduction band of the metal oxide is lower, by approximately 0.1 eV, than the LUMO level of the material (material included the buffer layer 15) having a property of blocking an exciton and having a glass transition temperature of, for example, greater than or equal to 415K, there is a concern that the electrons of the positive electrode 17 will flow toward the buffer layer 15 as a dark current due to the thermal energy at a room temperature.

For this reason, as the conduction band of the metal oxide is lower, by 0.5 eV or more, than the LUMO level of the material (material included the buffer layer 15) having a glass transition temperature of 415K or more and having a property of blocking an exciton as described above, it is possible to prevent the electrons of the positive electrode 17 from flowing toward the buffer layer 15 as a dark current.

In the case of using the aforementioned TCTA as the material having a glass transition temperature of 415K or more and having a property of blocking an exciton, it is preferable to use a metal oxide having a conduction band which is lower, by 0.5 eV or more, than the LUMO level of the TCTA.

As such metal oxide, for example, molybdenum oxide can be used.

The conduction band (corresponding to the LUMO level) of the molybdenum oxide is 6.7 eV. The molybdenum oxide is a metal oxide having a conduction band which is lower, by 4.3 eV, than the LUMO level of the TCTA of 2.4 eV.

In the case of using TCTA as the material which is included in the buffer layer 15, has a glass transition temperature of 415K or more, and has a property of blocking an exciton, and using molybdenum oxide as a metal oxide, for example, phthalocyanine (Sub-PC) can be used as an organic semiconductor material included in the organic photoelectric conversion layer 14.

In this case, the difference in HOMO level between TCTA and Sub-PC (the HOMO level is 5.6 eV and the LUMO level is 3.6 eV) is 0.1 eV, and it is possible to transfer holes to the buffer layer 15.

The hole mobility of SubPC is 8.95×10⁻⁸ cm²/Vs, the hole mobility of TCTA is higher than the hole mobility of SubPC by approximately four-digit number, and therefore it is possible to introduce the holes into the metal-oxide layer 16 without storing the holes generated from the organic photoelectric conversion layer 14.

Regarding the metal-oxide layer 16, the metal-oxide layer 16 may be a layer which photoelectrically converts light into power by itself and the metal-oxide layer 16 may be a layer which does not photoelectrically convert light into power by itself.

It is preferable that the metal-oxide layer 16 have a function of transporting holes or a function of transporting electrons.

It is preferable that the thickness of the metal-oxide layer 16 be suitably adjusted to be in the range of, for example, 5 nm to 200 nm.

In the case where the thickness of the metal-oxide layer 16 is less than 5 nm, there is a concern that the effect of preventing the dark current from flowing in the metal-oxide layer 16 (in other words, the effect of blocking electrons) will be reduced.

On the other hand, in the case where the thickness of the metal-oxide layer 16 is greater than 200 nm, there is a concern that the photoelectric conversion efficiency will be degraded.

Accordingly, as a result of determining the thickness of the metal-oxide layer 16 to be in the range of 5 nm to 200 nm, the dark current is prevented from being generated, and it is possible to prevent the photoelectric conversion efficiency from being degraded.

Particularly, the thickness of the metal-oxide layer 16 is preferably in the range of, for example, 5 nm to 100 nm.

In this case, the dark current can be prevented from being generated, and it is possible to further prevent the photoelectric conversion efficiency from being degraded.

The aforementioned metal-oxide layer 16 can be formed by a well-known method (for example, a vacuum deposition method).

The positive electrode 17 is provided so as to cover a top surface 16a (surface located near the positive electrode 17) of the metal-oxide layer 16.

As a material used to form the positive electrode 17, for example, the same material as that of the above-described negative electrode 12 can be used.

The thickness of the positive electrode 17 can be properly determined to be in the range of, for example, 5 to 150 nm.

The positive electrode 17 can be formed by a well-known method.

The organic photoelectric conversion device according to the first embodiment includes: the organic photoelectric conversion layer 14; the metal-oxide layer 16 including a metal oxide; and the buffer layer 15 which is arranged between the organic photoelectric conversion layer 14 and the metal-oxide layer 16 and includes the material having a glass transition temperature of 415K or more and having a property of blocking an exciton.

Accordingly, since the buffer layer 15 functions as an exciton blocking layer that prevents the excitons, which are generated from the organic photoelectric conversion layer 14, from transferring to the metal-oxide layer 16. Therefore, it is possible to improve the photoelectric conversion efficiency of the organic photoelectric conversion layer 14 as compared with a conventional organic photoelectric conversion device which does not include the buffer 15.

As a result of providing the buffer layer 15 between the organic photoelectric conversion layer 14 and the metal-oxide layer 16, the damage to the organic photoelectric conversion layer 14 when the metal-oxide layer 16 is formed can be reduced, and therefore it is possible to improve the photoelectric conversion efficiency of the organic photoelectric conversion layer 14.

In the first embodiment, the case is described where, for example, the positive-hole blocking layer 13 is provided as a constituent part of the organic photoelectric conversion device 10. In other cases, the positive-hole blocking layer 13 is not the essential constituent part, and it is only necessary to provide the positive-hole blocking layer 13 in the organic photoelectric conversion device 10 as appropriate.

The aforementioned organic photoelectric conversion device 10 is applicable to a solar cell.

### Second Embodiment

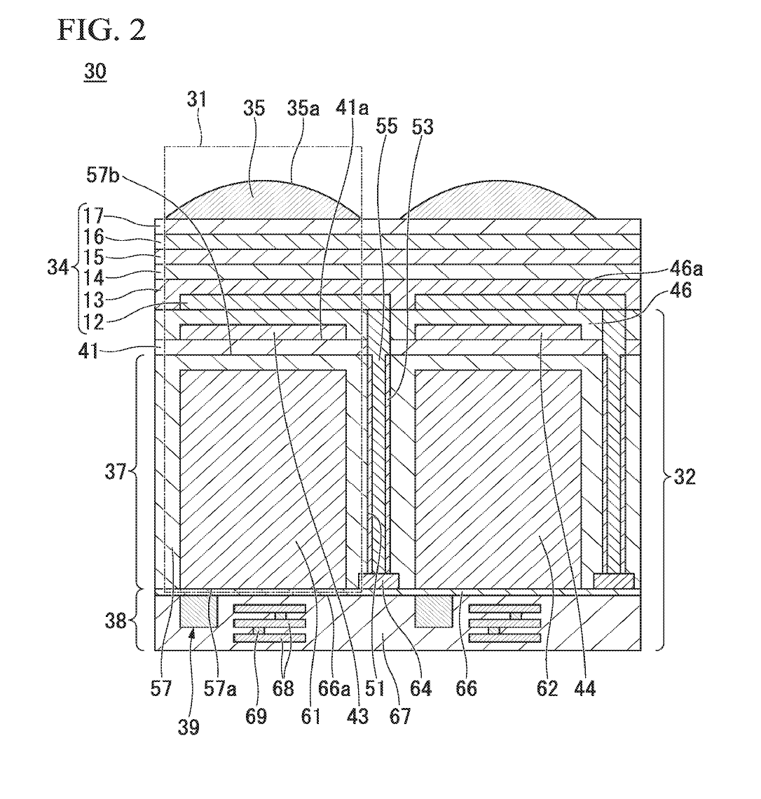

FIG. 2 is a cross-sectional view showing a main part (image capturer) of a solid-state image sensing device according to a second embodiment.

In FIG. 2, identical reference numerals are used for the elements which are identical to those of the organic photoelectric conversion device 10 shown in FIG. 1.

Particularly, a solid-state image sensing device 30 according to the second embodiment includes the image capturer (main part) as shown in FIG. 1 and a peripheral circuit unit arranged around the image capturer. In the second embodiment, the image capturer which will be described below is only shown in FIG. 2.

With reference to FIG. 2, the solid-state image sensing device 30 according to the second embodiment is configured to include a plurality of pixels 31 which are arranged in an array. The solid-state image sensing device 30 includes the substrate 32, a plurality of organic photoelectric converters 34, and a plurality of micro lenses 35.

In the second embodiment, the pixel 31 is a region that is formed in a quadrangular shape in a plan view and has four sides. The micro lens 35 has a face 35b that is formed in a circular shape and is a surface located on the opposite side of a light-receiving face 35a. The diameter (outer diameter) of the circular-shaped face 35b is equal to the length of the side of the quadrangular-shaped pixel 31.

The substrate 32 includes: a substrate main body 37; a multilayer wiring structure 38; transmission transistors 39; insulating films 41, 46, and 53; color filters 43 and 44; through holes 51; and contact plugs 55.

The substrate main body 37 includes: a semiconductor substrate 57; photodiodes 61 and 62 serving as a photoelectric converter; and SDs 64 (charge storage diode).

The semiconductor substrate 57 is a substrate having a reduced thickness and has a flat top surface 57a (first surface) and a back surface 57b (second surface).

As the semiconductor substrate 57, for example, a P-type single-crystalline silicon substrate can be used; however, it is not limited to this.

Hereinafter, as an example, the case where a P-type single-crystalline silicon substrate is used as the semiconductor substrate 57 will be described.

The photodiode 61 is provided inside the semiconductor substrate 57 located under the color filter 43.

The photodiode 61 is configured to include a first impurity diffusion region (not shown in the figure) that is exposed to the top surface 57a of the semiconductor substrate 57 and a second impurity diffusion region (not shown in the figure) that is connected to the top of the first impurity diffusion region.

As the first impurity diffusion region, for example, a high concentration P-type impurity diffusion region can be used.

In this case, as the second impurity diffusion region, a high concentration N-type impurity diffusion region can be used.

The photodiode 61 is arranged so as to the color filter 43 with part of the semiconductor substrate 57 interposed therebetween.

For example, in the case where the color filter 43 is a filter that allows red light to be transmitted therethrough, when the photodiode 61 receives red light, the photodiode 61 photoelectrically converts the red light into power and generates an electrical charge corresponding to the red light.

Particularly, the aforementioned red light means light having a wavelength-band of 600 to 780 nm.

The photodiode 62 is provided inside the semiconductor substrate 57 located under the color filter 44.

The photodiode 62 has the same configuration as that of the above-described photodiode 61.

The photodiode 62 is disposed so as to face the color filter 44 via part of the semiconductor substrate 57.

For example, in the case where the color filter 44 is a filter that allows blue light to be transmitted therethrough, when the photodiode 62 receives blue light, the photodiode 62 photoelectrically converts the blue light into power and generates an electrical charge corresponding to the blue light.

Particularly, the aforementioned blue light means light having a wavelength-band of 400 nm or more to less than 500 nm.

The above-mentioned photodiodes 61 and 62 are alternately arranged in the X-direction and the Y-direction.

The SD 64 is provided on the semiconductor substrate 57 located between the photodiodes 61 and 62.

The SD 64 is exposed at the top surface 57a of the semiconductor substrate 57.

The SD 64 is electrically connected through the contact plug 55 to the negative electrode 12 that constitutes the organic photoelectric converter 34.

The SD 64 a function of cumulatively storing an electrical charge generated from the organic photoelectric conversion layer 14.

For example, in the case where the organic photoelectric conversion layer 14 is a film that absorbs green light, the SD 64 cumulatively stores an electrical charge corresponding to green light that is received by the organic photoelectric conversion layer 14.

Particularly, the aforementioned green light means light having a wavelength-band of 500 to 600 nm.

As the SD 64, for example, a high concentration N-type impurity diffusion region can be used.

The multilayer wiring structure 38 includes a gate insulator film 66, insulating films 67, wirings 68, and via hole 69.

The gate insulator film 66 is provided so as to cover the top surface 57a of the semiconductor substrate 57.

The gate insulator film 66 is a film that functions as a gate insulator film of the transmission transistors 39.

The insulating films 67 are arranged and layered on a surface 66a of the gate insulator film 66 (surface located on the opposite side of the surface that is in contact with the top surface 57a of the semiconductor substrate 57).

The insulating films 67 are configured to include a plurality of insulating layers (for example, silicon oxide layers) that are stacked in layers in the thickness direction of the substrate 32 and that are not shown in the figure.

The wirings 68 are provided between the insulating layers.

The via hole 69 is provided so as to penetrate through the insulating layer 67 located between the wirings 68 layered in the vertical direction.

The via hole 69 electrically connects the wirings 68 layered in the vertical direction.

The transmission transistors 39 are provided at the semiconductor substrate 57 located near the boundary between the semiconductor substrate 57 and the multilayer wiring structure 38 and in part of the multilayer wiring structure 38.

Gate electrodes that constitute the transmission transistors 39 are arranged on the surface 66a of the gate insulator film 66.

The transmission transistor 39 electrically connects the wiring 68 and the via hole 69.

Each transmission transistor 39 functions as a reading transistor.

The transmission transistors 39 have a function of reading out the electrical charge cumulatively stored in the SD 64.

The insulating film 41 is provided on the back surface 57b of the semiconductor substrate 57.

As the insulating film 41, for example, a light-transmission resin can be used which has light transmittance of 80% or more with respect to visible light having a wavelength range of 380 to 780 nm.

The color filters 43 and 44 are provided on the top surfaces 41a of the insulating film 41 which correspond to the pixels 31.

The color filters 43 and 44 can be alternately arranged in, for example, an array.

The color filters 43 and 44 allow colored light to be transmitted therethrough where the colored light is selected from the group consisting of red light, blue light, and green light, the colored light is different from the colored light that is to be photoelectrically converted by the organic photoelectric conversion layer 14.

The color filter 44 allows colored light to be transmitted therethrough where the colored light is selected from the group consisting of red light, blue light, and green light, and the colored light is different from the colored light that is to be transmitted through the color filter 43.

For example, in the case of using an organic photoelectric conversion layer that photoelectrically converts green light into power (hereinbelow, referred to as “green-light organic photoelectric conversion layer”) as the organic photoelectric conversion layer 14, a color filter that allows red light to be transmitted therethrough and a color filter that allows blue light to be transmitted therethrough can be used as the color filters 43 and 44, respectively.

In the case of using an organic photoelectric conversion layer that photoelectrically converts red light into power (hereinbelow, referred to as “red-light organic photoelectric conversion layer”) as the organic photoelectric conversion layer 14, a color filter that allows blue light to be transmitted therethrough and a color filter that allows green light to be transmitted therethrough can be used as the color filters 43 and 44, respectively.

In the case of using an organic photoelectric conversion layer that photoelectrically converts blue light into power (hereinbelow, referred to as “blue-light organic photoelectric conversion layer”) as the organic photoelectric conversion layer 14, a color filter that allows red light to be transmitted therethrough and a color filter that allows green light to be transmitted therethrough can be used as the color filters 43 and 44, respectively.

Here, from the wavelength-bands of the above-mentioned green light, red light, and blue light, it is apparent that the wavelength of the red light is longest and the wavelength of the blue light is shortest in the green light, the red light, and the blue light, and that the wavelength of the green light is located between the wavelength of the red light and the wavelength of the blue light.

For this reason, as a result of using an organic photoelectric conversion layer that photoelectrically converts green light into power as the organic photoelectric conversion layer 14 and providing the color fillers 43 and 44 which allow one of the red light and the blue light to be transmitted therethrough under the organic photoelectric conversion layer 14, it is possible to carry out color separation between the red light and the blue light with a high level of accuracy.

The insulating film 46 is provided on the top surface 41a of the insulating film 41 so as to cover the plurality of the color filters 43 and 44.

The insulating film 46 has a flat top surface 46a.

The top surface 46a of the insulating film 46 is a surface corresponding to the top surface of the substrate 32.

The through holes 51 are provided so as to penetrate through the semiconductor substrate 57 and the insulating films 41 and 46 which are located above the SD 64.

The through hole 51 exposes the top surface of the SD 64.

The insulating film 53 is provided so as to cover the inner wall which is part of the through hole 51 and is formed in the semiconductor substrate 57.

The contact plug 55 is formed so as to fill the through hole 51 in which the insulating film 53 is formed.

Accordingly, the lower end of the contact plug 55 is connected to the SD 64.

The upper end of the contact plug 55 is exposed at the top surface 46a of the insulating film 46.

The contact plug 55 can be formed of, for example, a metal bather layer and a tungsten film.

In the configuration of each of the organic photoelectric converters 34, the negative electrode 12, the positive-hole blocking layer 13, the organic photoelectric conversion layer 14, the buffer layer 15, the metal-oxide layer 16, and the positive electrode 17 are stacked in order. One organic photoelectric converter 34 is provided in each pixel 31.

The negative electrode 12 is provided on the top surface 46a of the insulating film 46 corresponding to each pixel 31.

The negative electrodes 12 are configured to be separated from each other.

The negative electrode 12 is connected to the contact plug 55.

In this structure, the electrical charge generated from the organic photoelectric conversion layer 14 is cumulatively stored in the SD 64 through the contact plug 55.

The negative electrode 12 is made of a material having optical transparency.

In the second embodiment, “having optical transparency” means the characteristics that can cause 80% or more of visible light having a wavelength range of 380 to 780 nm to be transmitted through the material.

As a material used to form the negative electrode 12 constituting the organic photoelectric converter 34, for example, a material having optical transparency (for example, indium tin oxide (ITO)), which is selected from the materials used to form the negative electrode 12 (refer to FIG. 1) constituting the organic photoelectric conversion device 10 described in the first embodiment, can be used.

The thickness of the negative electrode 12 is preferably in the range of for example, 10 nm to 300 nm.

In the case where the thickness of the negative electrode 12 is less than 10 nm, there is a possibility that the electrical resistance thereof increases.

On the other hand, in the case where the thickness of the negative electrode 12 is greater than 300 nm, since the stress of the film constituting the negative electrode 12 increases, there is a possibility that a crack occurs or the transmittance of the light transmitting through the negative electrode 12 is degraded.

Consequently, as a result of determining the thickness of the negative electrode 12 to be in the range of 10 nm to 300 nm, the electrical resistance thereof is prevented from being higher, a crack is prevented from being generated, and furthermore the light transmittance can be sufficiently ensured.

The positive-hole blocking layer 13 is provided on the top surface 46a of the insulating film 46 so as to cover the plurality of the negative electrodes 12.

The positive-hole blocking layer 13 is provided so as to cover the plurality of the pixels 31 and bridge between the pixels 31.

Therefore, the positive-hole blocking layer 13 functions as a positive-hole blocking layer which is common to the plurality of the pixels 31.

The thickness of the positive-hole blocking layer 13 can be properly selected to be in the range of, for example, 1 nm to 100 nm.

The organic photoelectric conversion layer 14 is provided so as to cover the top surface of the positive-hole blocking layer 13.

Particularly, the organic photoelectric conversion layer 14 is provided so as to cover the plurality of the pixels 31 and bridge between the pixels 31.

Therefore, the organic photoelectric conversion layer 14 functions as an organic photoelectric conversion layer which is common to the plurality of the pixels 31.

The organic photoelectric conversion layer 14 is configured to photoelectrically convert, into power, one of red light, blue light, and green light which are included in the light received by the organic photoelectric conversion layer 14.

As the organic photoelectric conversion layer 14 constituting the solid-state image sensing device 30, for example, one selected from the group consisting of a green-light organic photoelectric conversion layer, a red-light organic photoelectric conversion layer, and a blue-light organic photoelectric conversion layer can be used.

As a material used to form the green-light organic photoelectric conversion layer, for example, at least one material selected from the group consisting of a quinacridone derivative, a perylene bisimide derivative, an oligothiophene derivative, a subphthalocyanine derivative, a rhodamine compound, and a ketocyanine derivative can be used.

As a material used to form the red-light organic photoelectric conversion layer, for example, at least one material selected from the group consisting of a phthalocyanine derivative, a squarylium derivative, and a subnaphthalocyanine derivative can be used.

As a material used to form the blue-light organic photoelectric conversion layer, for example, at least one material selected from the group consisting of a porphyrincobalt complex, a coumarin derivative, fullerene, a fullerene derivative, a florene compound, and a pyrazole derivative can be used.

Moreover, at least one additive selected from the group consisting of, for example, a phthalocyanine derivative, a squarylium derivative, and a subnaphthalocyanine derivative may be added to the above-described material used to form the green-light organic photoelectric conversion layer.

Consequently, in the green-light organic photoelectric conversion layer, it is possible to absorb the energy corresponding to that of red light, and it is thereby possible to prevent red light emission from being generated in the green-light organic photoelectric conversion layer.

Moreover, at least one additive selected from the group consisting of, for example, a quinacridone derivative, a perylene bisimide derivative, an oligothiophene derivative, a subphthalocyanine derivative, a rhodamine compound, and a ketocyanine derivative may be added to the above-described material used to form the blue-light organic photoelectric conversion layer.

Consequently, in the blue-light organic photoelectric conversion layer, it is possible to absorb the energy corresponding to that of green light, and it is thereby possible to prevent green light emission from being generated in the blue-light organic photoelectric conversion layer.

It is preferable that the thickness of the organic photoelectric conversion layer 14 constituting the solid-state image sensing device 30 be suitably adjusted to be in the range of, for example, 30 nm 300 nm.

In the case where the thickness of the organic photoelectric conversion layer 14 is less than 30 nm, there is a possibility that it is difficult to sufficiently ensure the photoelectric conversion efficiency of the organic photoelectric conversion layer 14.

On the other hand, in the case where the thickness of the organic photoelectric conversion layer 14 is greater than 300 nm, there is a possibility that the voltage to be applied to the organic photoelectric conversion layer 14 becomes higher, and therefore there is a concern that it will not be suitable for reducing power consumption.

Furthermore, in the case where the thickness of the organic photoelectric conversion layer 14 is greater than 300 nm, there is a possibility that the transmittance of colored light other than the colored light (one of red light, blue light, and green light) which is to be absorbed by the organic photoelectric conversion layer 14 becomes degraded.

Because of this, as a result of determining the thickness of the organic photoelectric conversion layer 14 to be in the range of 30 nm to 300 nm, light having a color other than the color of the light absorbed by the organic photoelectric conversion layer 14 can be sufficiently transmitted therethrough without applying a high voltage thereto, and it is also possible to sufficiently ensure the photoelectric conversion efficiency of the organic photoelectric conversion layer 14.

The buffer layer 15 is provided so as to cover the top surface of the organic photoelectric conversion layer 14.

The buffer layer 15 is a buffer layer common to the plurality of the pixels 31.

As a material used to form the buffer layer 15 constituting the organic photoelectric converter 34, for example, the same material as the material (for example, TCTA) of the buffer layer 15 described in the first embodiment can be used.

As described in the first embodiment, it is preferable that the thickness of the buffer layer 15 be in the range of, for example, 5 nm to 200 nm.

The metal-oxide layer 16 is provided so as to cover the top surface of the buffer layer 15.

The metal-oxide layer 16 is a metal-oxide layer common to the plurality of the pixels 31.

As the metal oxide included in the metal-oxide layer 16 constituting the organic photoelectric converter 34, for example, the same material that of the metal oxide described in the first embodiment can be used.

As described in the first embodiment, it is preferable that the thickness of the metal-oxide layer 16 be suitably adjusted to be in the range of, for example, 5 nm to 200 nm.

The positive electrode 17 is provided so as to cover the top surface of the metal-oxide layer 16.

The positive electrode 17 is provided so as to cover the plurality of the pixels 31 and bridge between the pixels 31.

Therefore, the positive electrode 17 functions as an electrode common to the plurality of the pixels 31.

The positive electrode 17 is an electrode having optical transparency.

As a material used to form the positive electrode 17 constituting the organic photoelectric converter 34, for example, a material having optical transparency (for example, indium tin oxide (ITO)), which is selected from the materials used to form the positive electrode 17 (refer to FIG. 1) constituting the organic photoelectric conversion device 10 described in the first embodiment, can be used.

It is preferable that the thickness of the positive electrode 17 be suitably adjusted to be in the range of, for example, 10 nm 300 nm.

In the case where the thickness of the positive electrode 17 is less than 10 nm, there is a possibility that the electrical resistance thereof increases.

On the other hand, in the case where the thickness of the positive electrode 17 is greater than 300 nm, since the stress of the film constituting the positive electrode 17 increases, there is a possibility that a crack occurs.

Consequently, as a result of determining the thickness of the positive electrode 17 to be in the range of 10 nm to 300 nm, the electrical resistance thereof is prevented from being higher, and a crack is prevented from being generated.

The micro lens 35 is a lens used to collect light, and each lens is provided so as to correspond to one of the pixels 31 that are arranged in an array.

The micro lenses 35 are arranged in an array and are separated from each other at a predetermined distance.

Consequently, a gap is formed between the micro lenses 35.

The micro lenses 35 are provided on the positive electrode 17 so as to face the color filter 43 or the color filter 44. The organic photoelectric converter 34 and the insulating film 46 are interposed between the micro lens 35 and the color filter 43 and between the micro lens 35 and the color filter 44.

The micro lens 35 has the light-receiving face 35a having a curved surface formed in a convex shape and the face 35b serving as a flat surface disposed on the opposite side of the light-receiving face 35a.

As a film used to form the micro lenses 35, for example, it is preferable to use a film having both resistance to chemical agents which are used in the steps of forming the negative electrode 12, the positive-hole blocking layer 13, the organic photoelectric conversion layer 14, and the positive electrode 17, and resistance to a high temperature in the steps of forming the electrodes 12 and 17 and the layers 13 and 14.

As the film used to form the micro lenses 35 and satisfying the above-described conditions, for example, an oxide film such as a TEOS (Tetra Ethyl Ortho Silicate) film can be adopted.

The solid-state image sensing device according to the second embodiment includes: the organic photoelectric conversion layer that photoelectrically converts light into power; the metal-oxide layer including a metal oxide; and the buffer layer which is arranged between the organic photoelectric conversion layer and the metal-oxide layer and includes the material having a glass transition temperature of 415K or more and having a property of blocking an exciton.

Accordingly, since the buffer layer 15 functions as an exciton blocking layer that prevents the excitons, which are generated from the organic photoelectric conversion layer 14, from transferring to the metal-oxide layer 16. Therefore, it is possible to improve the photoelectric conversion efficiency of the organic photoelectric conversion layer 14 as compared with a conventional solid-state image sensing device which does not include the buffer 15.

As a result of providing the buffer layer 15 between the organic photoelectric conversion layer 14 and the metal-oxide layer 16, the damage to the organic photoelectric conversion layer 14 when the metal-oxide layer 16 is formed can be reduced, and therefore it is possible to improve the photoelectric conversion efficiency of the organic photoelectric conversion layer 14.

Next, a method of manufacturing the solid-state image sensing device 30 according to the second embodiment will be described with reference to FIG. 2.

First of all, a semiconductor substrate 57 which is not thinned is prepared.

As the semiconductor substrate 57, for example, a P-type single-crystalline silicon substrate can be used.

Hereinafter, as an example, the case where a P-type single-crystalline silicon substrate is used as the semiconductor substrate 57 will be described.

Next, the photodiodes 61 and 62 and the SD 64 are formed by well-known methods.

Particularly, the photodiodes 61 and 62 are formed by, for example, causing the semiconductor substrate 57 to be subjected to ion implantation with P-type impurities (for example, boron), next causing it to be subjected to ion implantation with N-type impurities (for example, phosphorus), and thereafter causing it to be subjected to annealing processing.

The SD 64 is formed by causing the semiconductor substrate 57 to be subjected to ion implantation with N-type impurities (for example, phosphorus) and thereafter causing it to be subjected to annealing processing.

Subsequently, the multilayer wiring structure 38 and the transmission transistor 39 are formed on the top surface 57a of the semiconductor substrate 57 by well-known methods.

After that, using well-known methods, the thickness of the semiconductor substrate 57 is reduced by thinning the semiconductor substrate 57 from the back surface 57b thereof.

At this time, the semiconductor substrate 57 is thinned so that the photodiodes 61 and 62 are not exposed to the back surface thereof.

After that, the insulating film 41, the color filters 43 and 44, and the insulating film 46 are sequentially formed by well-known methods.

When the color filters 43 and 44 are formed, for example, a step of applying a first color resist (not shown in the figure) on the insulating film 41 and carrying out exposure and developing processes and a step of applying a second color resist (not shown in the figure) which is different from the first color resist on the insulating film 41 and carrying out exposure and developing processes are performed, and the color filters 43 and 44 which allow various color light to be transmitted therethrough are thereby formed.

Next, the semiconductor substrate 57 located above the SD 64, the insulating film 41, and the insulating film 46 are by an anisotropic dry etching method, and the through holes 51 which expose the top surface of the SD 64 is formed.

Subsequently, the insulating film 53 that covers the side wall of the through hole 51 and the contact plug 55 are sequentially formed by well-known methods.

Accordingly, the substrate 32 is formed.

After that, the negative electrode 12 is formed on the top surface 46a of the insulating film 46 which constitutes each pixel 31 by well-known methods.

Specifically, the negative electrode 12 can be formed by the following method.

First of all, a light transmitting conductive film (for example, ITO (Indium Tin Oxide) film) which serves as a base material used to form the negative electrode 12 and is not shown in the figure is formed.

In the case of using an ITO film as the light transmitting conductive film, the ITO film can be formed by methods such as an electron beam method, a sputtering method, a resistance heating deposition method, a chemical reaction method (for example, a sol-gel method), or a method of applying a dispersed material including indium tin oxide on the top surface.

Next, the light transmitting conductive film is separated into a plurality of electrodes by a well-known photolithographic technique and a dry etching technique, and a plurality of negative electrodes 12 made of the light transmitting conductive film is thereby formed.

The thickness of the negative electrode 12 is preferably in the range of, for example, 10 nm to 300 nm.

Subsequently, the positive-hole blocking layer 13 that covers the plurality of the negative electrodes 12 is formed on the top surface 46a of the insulating film 46.

Consequently, the positive-hole blocking layer 13 is formed so as to cover the plurality of the pixels 31 and bridge between the pixels 31.

Here, as a method of forming the positive-hole blocking layer 13, for example, a method such as a coating method or a vacuum deposition method can be used.

It is preferable that the thickness of the positive-hole blocking layer 13 be suitably adjusted to be in the range of, for example, 1 nm to 100 nm.

After that, the organic photoelectric conversion layer 14 that covers the top surface of the positive-hole blocking layer 13 is formed.

Consequently, the organic photoelectric conversion layer 14 is formed so as to cover the plurality of the pixels 31 and bridge between the pixels 31.

In this situation, as a method for forming the organic photoelectric conversion layer 14, the same method as the method for forming the organic photoelectric conversion layer 14 which is described in the first embodiment can be used.

It is preferable that the thickness of the organic photoelectric conversion layer 14 be suitably adjusted to be in the range of, for example, 30 nm to 300 nm.

Next, the buffer layer 15 that covers the top surface of the organic photoelectric conversion layer 14 is formed.

Consequently, the buffer layer 15 is formed so as to cover the plurality of the pixels 31 and bridge between the pixels 31.

The buffer layer 15 is formed by, for example, a vapor-deposition method.

In the case of forming the buffer layer 15 using a vapor-deposition method, the same deposition conditions as the deposition conditions described in the first embodiment can be used.

The thickness of the buffer layer 15 is preferably in the range of, for example, 5 nm to 200 nm.

Subsequently, the metal-oxide layer 16 that covers the top surface of the buffer layer 15 is formed by well-known methods (for example, a vacuum deposition method).

Consequently, the metal-oxide layer 16 is formed so as to cover the plurality of the pixels 31 and bridge between the pixels 31.

It is preferable that the thickness of the metal-oxide layer 16 be suitably adjusted to be in the range of for example, 5 nm to 200 nm.

After that, the positive electrode 17 that covers the top surface of the metal-oxide layer 16 is formed so as to cover the plurality of the pixels 31 and bridge between the pixels 31 by well-known methods.

Consequently, the organic photoelectric converter 34 that is configured by the negative electrode 12, the positive-hole blocking layer 13, the organic photoelectric conversion layer 14, the buffer layer 15, the metal-oxide layer 16, and the positive electrode 17 is formed.

Next, the micro lenses 35 are formed on the top surface of the positive electrode 17 corresponding to each pixel 31 by well-known methods.

Specifically, the micro lenses 35 can be formed by, for example, the following method.

Firstly, an oxide film (for example, TEOS film) that covers the top surface of the positive electrode 17 is formed by, for example, a CVD (Chemical Vapor Deposition) method.

Next, a resist film (not shown in the figure) having a plurality of projecting portions formed in a convex lens shape (the projecting portion is provided on each pixel 31) is formed by well-known methods.

Thereafter, as a result of carrying out an anisotropic dry etching using the resist film as an etching mask until the top surface of the positive electrode 17 is exposed, a plurality of micro lenses 35, each of which has the light-receiving face 35a serving as a curved surface formed in a convex shape, are formed.

Accordingly, the solid-state image sensing device 30 according to the second embodiment is manufactured.

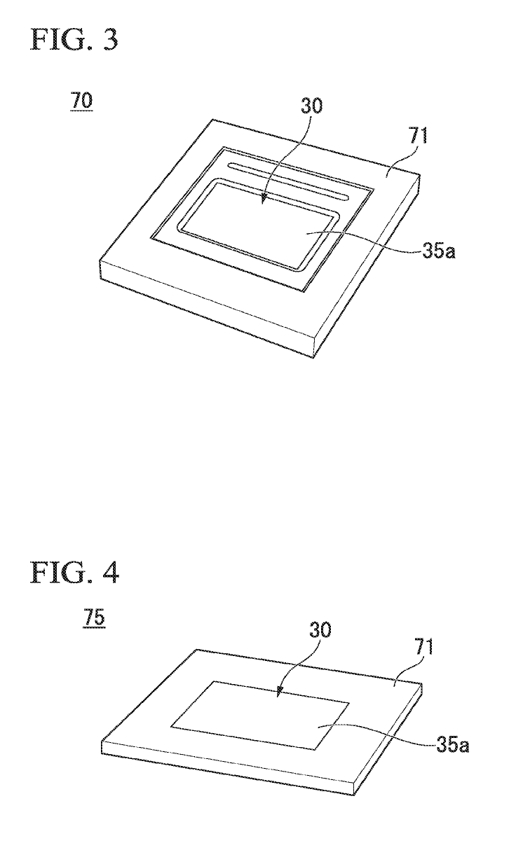

FIG. 3 is a perspective view showing an example of a CMOS image sensor to which the solid-state image sensing device according to the second embodiment is applied.

In FIG. 3, identical reference numerals are used for the elements which are identical to those of FIG. 2.

Here, an example of a CMOS image sensor 70 to which the solid-state image sensing device 30 according to the second embodiment is applied will be described with reference to FIGS. 2 and 3.

The CMOS image sensor 70 is a Full-HD (1080p) CMOS image sensor.

The CMOS image sensor 70 includes the solid-state image sensing device 30, a plurality of solder balls serving as external connection terminals (not shown in the figure), and a sealing resin 71.

The solder balls (not shown in the figure) are provided on the surface of the solid-state image sensing device 30 which is located on the opposite side of the light-receiving face 35a.

The solder balls (not shown in the figure) are electrically connected to the wirings 68 and the via holes 69 which constitute the multilayer wiring structure 38.

The sealing resin 71 seals the solid-state image sensing device 30 in a state where the light-receiving face 35a and the solder balls (not shown in the figure) are exposed to the outside of the CMOS image sensor 70.

The sealing resin 71, for example, a molded resin formed by a transfer mold method can be used.

The solid-state image sensing device 30 according to the second embodiment is used in an imaging device, for example, digital cameras, mobile terminals such as portable telephones (including smartphones), monitoring cameras, web cameras utilizing the internet, and the like, in a state where the solid-state image sensing device 30 is incorporated into the CMOS image sensor 70 as a part thereof.

FIG. 4 is a perspective view showing another example of a CMOS image sensor to which the solid-state image sensing device according to the second embodiment is applied.

In FIG. 4, identical reference numerals are used for the elements which are identical to those of FIG. 3.

Here, a CMOS image sensor 75 which is different from the CMOS image sensor 70 shown in FIG. 3 and to which the solid-state image sensing device 30 according to the second embodiment is applied will be described with reference to FIGS. 2 and 4.

The CMOS image sensor 75 is a VGA CMOS image sensor.

The CMOS image sensor 75 is a chip size package to which TSV (Through Silicon Via) technique is applied.

The CMOS image sensor 75 includes the solid-state image sensing device 30, a plurality of solder balls serving as external connection terminals (not shown in the figure), and a sealing resin 71.

The solid-state image sensing device 30 according to the second embodiment is widely used in various fields in, for example, digital cameras, mobile terminals such as portable telephones (including smartphones), monitoring cameras, web cameras utilizing the internet, or the like, in a state where the solid-state image sensing device 30 is incorporated into the CMOS image sensor 75 as a part thereof.

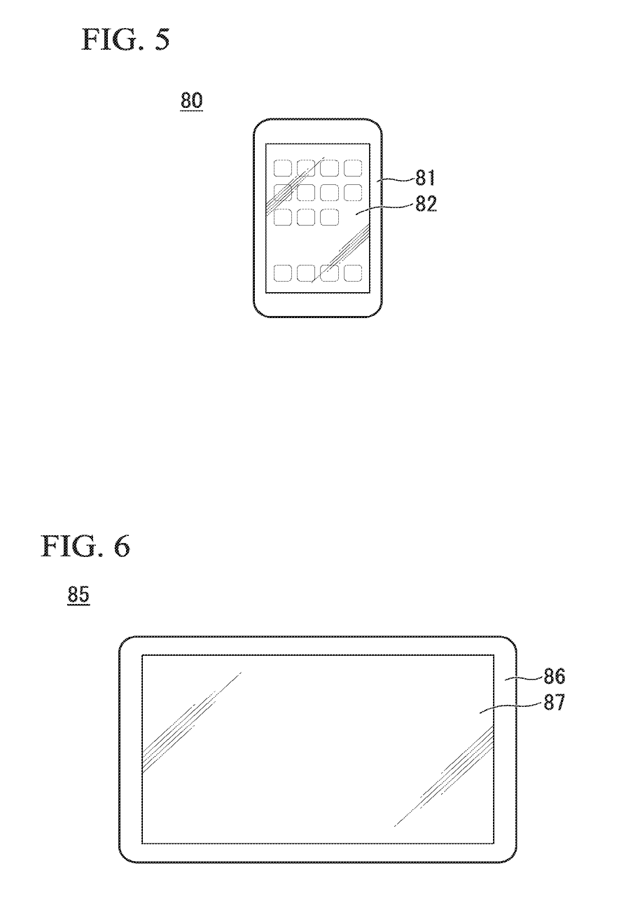

FIG. 5 is a plan view showing a smartphone serving as an imaging device provided with a CMOS image sensor built therein.

With reference to FIG. 5, a smartphone 80 is an imaging device and includes a smartphone body 81, an operation screen 82 (touch panel), and a camera module (not shown in the figure).

The camera module (not shown in the figure) includes: a lens (not shown in the figure); and the CMOS image sensor 70 (refer to FIG. 3) or the CMOS image sensor 75 (refer to FIG. 4).

The lens (not shown in the figure) is exposed at the surface of the smartphone body 81 which is located on the opposite side of the operation screen 82.

The CMOS image sensors 70 and 75 are provided inside the smartphone body 81 so that the lens faces the light-receiving face 35a (refer to FIGS. 3 and 4).

As described above, the CMOS image sensors 70 and 75 are applicable to the smartphone 80.

In other cases, the CMOS image sensors 70 and 75 are also applicable to a camera module of a feature phone.

FIG. 6 is a plan view showing a tablet terminal device serving as an imaging device provided with a CMOS image sensor built therein.

With reference to FIG. 6, a tablet terminal device 85 is an imaging device, a tablet main body 86, an operation screen 87 (touch panel), and a camera module (not shown in the figure).

The camera module (not shown in the figure) includes: a lens (not shown in the figure); and the CMOS image sensor 70 (refer to FIG. 3) or the CMOS image sensor 75 (refer to FIG. 4).

The lens (not shown in the figure) is exposed at the surface of the tablet main body 86 which is located on the opposite side of the operation screen 87.

The CMOS image sensors 70 and 75 are provided inside the tablet main body 86 so that the lens faces the light-receiving face 35a (refer to FIGS. 3 and 4).

As described above, the CMOS image sensors 70 and 75 are applicable to not only the smartphone 80 shown in FIG. 5 but also the tablet terminal device 85.

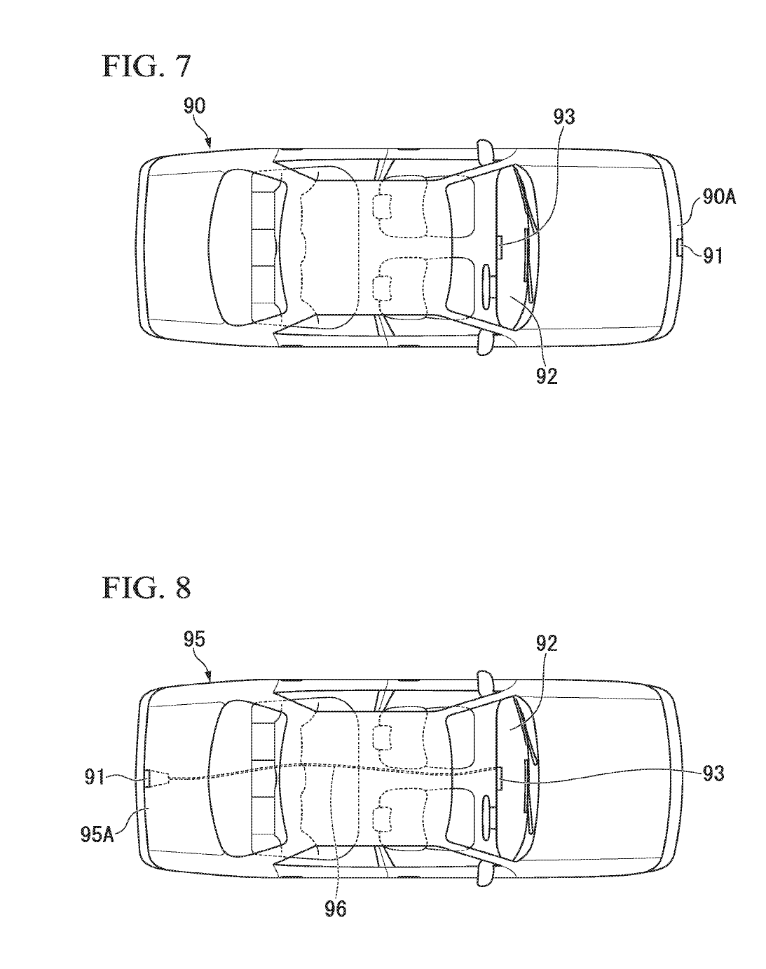

FIG. 7 is a plan view showing an example of an automobile that is provided with a car-mounted camera serving as an imaging device and an image display device.

With reference to FIG. 7, a car-mounted camera 91 is an imaging device and provided at a front end 90A of an automobile 90.

The CMOS image sensor 70 (refer to FIG. 3) or the CMOS image sensor 75 (refer to FIG. 4) is built in the car-mounted camera 91.

The car-mounted camera 91 is electrically connected to an image display device 93 (for example, display) that is fixed on an instrument panel 92 and at the position at which a driver can look a screen.

The car-mounted camera 91 image-captures an image in front of the automobile 90 and simultaneously shows the image captured by the image display device 93 on the screen.

Consequently, it allows the driver to check blind spots of the automobile or provide information to a driver parking the automobile.

As stated above, the CMOS image sensors 70 and 75 are applicable to the car-mounted camera 91.

FIG. 8 is a plan view showing another example of an automobile that is provided with a car-mounted camera serving as an imaging device and an image display device.

In FIG. 8, identical reference numerals are used for the elements which are identical to those of FIG. 7.

With reference to FIG. 8, an automobile 95 has the same configuration as that of the automobile 90 shown in FIG. 7 except that a car-mounted camera 91 is provided at a back end 95A of the automobile 95 via a wiring 96 and is electrically connected to the image display device 93.

As mentioned above, as the car-mounted camera 91 that is electrically connected to the image display device 93 is provided at the back end 95A of the automobile 95, it allows the driver to check an area behind the automobile.

Particularly, in FIGS. 7 and 8, the case where the car-mounted camera 91 is provided on the front end 90A or the back end 95A is described as an example; however, the number of and the position of the car-mounted cameras 91 are not limited to this.

For example, the car-mounted camera 91 may be provided on both the front end and the back end of the automobiles 90 and 95.

Moreover, the car-mounted camera 91 may be provided on a side surface portion of the automobiles 90 and 95.

The smartphone 80 shown in FIG. 5, the tablet terminal device 85 shown in FIG. 5, and the automobiles 90 and 95 shown in FIGS. 7 and 8 which are described above are examples of imaging devices to which the CMOS image sensors 70 and 75 shown in FIGS. 3 and 4 is applied, and the imaging devices are not limited to this.

The CMOS image sensors 70 and 75 are also applicable to, for example, digital cameras, mobile terminals other than portable telephones (including smartphones), monitoring cameras, web cameras utilizing the internet, and the like.

According to at least one of the above-described embodiments, as a result of providing the buffer layer 15 between the organic photoelectric conversion layer 14 and the metal-oxide layer 16 where the buffer layer 15 has a glass transition temperature of 415K or more and includes the material having a property of blocking an exciton, it is possible to improve the photoelectric conversion efficiency of the organic photoelectric conversion layer 14.

### Examples

Hereinbelow, Example 1 will be described.

The organic photoelectric conversion device of Example 1 having the same layered structure as that of the organic photoelectric conversion device 10 according to the first embodiment was manufactured.

Specifically, in the organic photoelectric conversion device of Example 1, the members were stacked in order as follows: a glass substrate (substrate) having a thickness of 700 μm/an ITO film (negative electrode) having a thickness of 50 nm/a PEIE layer (positive-hole blocking layer) having a thickness of 5 nm/an organic photoelectric conversion layer made of a SubPC (HOMO level is 5.6 eV) and F5-SubPC (HOMO level is 5.9 eV) and having a thickness of 200 nm/a TCTA layer (buffer layer) having a thickness of 10 nm/a molybdenum oxide layer (metal-oxide layer) having a thickness of 10 nm/an Al layer (positive electrode) having a thickness of 6 nm.

Particularly, the HOMO level of the TCTA is lower than the HOMO level of the SubPC by approximately 0.1 eV, and the LUMO level of the molybdenum oxide is lower than the LUMO level of the TCTA by 4.3 eV.

The organic photoelectric conversion device of Example 1 was manufactured by the following method.

First of all, an ITO-attached substrate (a glass substrate having a thickness of 700 μM/an ITO film having a thickness of 50 nm) was prepared, and thereafter the surface of the ITO-attached substrate was cleaned by UV/O₃.

Next, the ITO film was coated with the PEIE by applying the PEIE on the top surface of the ITO film using a spin coating method in an air atmosphere, and the PEIE layer having a thickness of 5 nm was formed.

Subsequently, a pressure inside a film formation chamber of a deposition apparatus was in a vacuum state of approximately 10⁻⁴ Pa, codeposition was carried out at a room temperature using a raw material having a weight ratio of Sub PC:F5-SubPC=1:1, and an organic photoelectric conversion layer having a thickness of 200 nm was thereby formed on the top surface of the PEIE layer.

After that, the top surface of the organic photoelectric conversion layer was coated with TCTA by a vapor-deposition method heating TCTA provided a crucible at the temperature of 298° C., and the TCTA layer having a thickness of 10 nm was thereby formed.

At this time, the film-forming rate of the TCTA layer was 0.05 nm/sec.

Next, a molybdenum trioxide layer that coats the top surface of the TCTA layer and has a thickness of 10 nm was formed by a vapor-deposition method.

At this time, the film-forming rate of the molybdenum trioxide layer was 0.031 nm/sec.

Subsequently, the Al layer that coats the top surface of the TCTA layer and has a thickness of 6 nm was formed by a vacuum deposition method.

Thereafter, a glass sealing substrate was adhesively attached to the glass substrate constituting the organic photoelectric conversion device of Example 1 by use of a UV-curable seal material.

Subsequently, the external quantum efficiency of the organic photoelectric conversion device of Example 1 to which the glass sealing substrate is adhesively attached was calculated.

Here, a method of calculating the external quantum efficiency of the organic photoelectric conversion device of Example 1 will be described.

First of all, by using CEP-V25ML which is a spectral sensitivity measurement apparatus produced by Bunkoukeiki Co., Ltd., the number of photons of illumination light of CEP-V25ML was set to be 1×10⁻¹⁴/cm²·s at a wavelength of 530 nm.

In the case where the surface area of the photoelectric conversion region is set to be 4 mm² (the surface area is 2 mm square), the number of photons which enter the photoelectric conversion region by light irradiation was 4×10⁻¹²/s.

At this time, the output electrical current A (ampere, λ) was measured, and the measured value was 2.99×10⁻⁷ A.

If it is assumed that the elementary charge is 1.6×10⁻¹⁹ [c], the number of the flowing electrons per unit time was 1.87×10⁻¹²/s.

Based on the number of the flowing electrons with respect to the photons of illumination light, the external quantum efficiency of the organic photoelectric conversion device of Example 1 was 47%.

Hereinbelow, the Comparative Example 1 will be described.

The organic photoelectric conversion device of the Comparative Example 1 is different from the organic photoelectric conversion device of Example 1 in that a buffer layer is not provided in the organic photoelectric conversion device of the Comparative Example 1.

The other configurations (the kinds of film, and the thickness of the film, or the like) of the organic photoelectric conversion device of the Comparative Example 1 are the same as those of the organic photoelectric conversion device of Example 1.

That is, in the organic photoelectric conversion device of the Comparative Example 1, the members were stacked in order as follows: a glass substrate (substrate) having a thickness of 700 μm/an ITO film (negative electrode) having a thickness of 50 nm/a PEIE layer (positive-hole blocking layer) having a thickness of 5 nm/an organic photoelectric conversion layer made of a SubPC and F5-SubPC and having a thickness of 200 nm/a molybdenum oxide layer (metal-oxide layer) having a thickness of 10 nm/an Al layer (positive electrode) having a thickness of 6 nm.

The organic photoelectric conversion device of the Comparative Example 1 was manufactured by the same method as the method of manufacturing the organic photoelectric conversion device of Example 1.

Thereafter, a glass sealing substrate was adhesively attached to the glass substrate constituting the organic photoelectric conversion device of the Comparative Example 1 by use of a UV-curable seal material.

Next, the external quantum efficiency of the organic photoelectric conversion device of the Comparative Example 1 to which the glass sealing substrate is adhesively attached was calculated by the same conditions and method as those of Example 1.

The external quantum efficiency of the organic photoelectric conversion device of the Comparative Example 1 was 27.1%.

Hereinbelow, the Comparative Example 2 will be described.

The organic photoelectric conversion device of the Comparative Example 2 is different from the organic photoelectric conversion device of Example 1 in that a TAPC layer having a thickness of 10 nm (the material of the TAPC layer has a glass transition temperature less than 415K) is used as the buffer layer in the organic photoelectric conversion device of the Comparative Example 2.

The other configurations of the organic photoelectric conversion device of the Comparative Example 2 are the same as those of the organic photoelectric conversion device of Example 1.

The glass transition temperature of the TAPC layer is 355K.

The organic photoelectric conversion device of the Comparative Example 2 was manufactured by the same method as the method of manufacturing the organic photoelectric conversion device of Example 1.

Thereafter, a glass sealing substrate was adhesively attached to the glass substrate constituting the organic photoelectric conversion device of the Comparative Example 2 by use of a UV-curable seal material.

Next, the external quantum efficiency of the organic photoelectric conversion device of the Comparative Example 2 to which the glass sealing substrate is adhesively attached was calculated by the same conditions and method as those of Example 1.

The external quantum efficiency of the organic photoelectric conversion device of the Comparative Example 2 was 31.3%.

From the results of the external quantum efficiencies of the Comparative Examples 1 and 2, it is understood that, in the case where a buffer layer is present between the organic photoelectric conversion layer and the metal-oxide layer, the external quantum efficiency is improved by approximately 4.2%.

From the results of the external quantum efficiencies of Example 1 and the Comparative Example 1, as a result of forming the buffer layer by use of TCTA which is the material having a glass transition temperature of 415K or more and having a property of blocking an exciton, it can be evaluated that the external quantum efficiency of Example 1 is improved by approximately 15.3% to be higher than the case of forming the buffer layer using TAPC having a glass transition temperature of 355K.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An organic photoelectric conversion device comprising:
an organic photoelectric conversion layer;
a metal-oxide layer including a metal oxide; and
a buffer layer provided between the organic photoelectric conversion layer and the metal-oxide layer, the buffer layer including a material having a glass transition temperature of 415K or more and having a property of blocking an exciton.

2. The organic photoelectric conversion device according to claim 1, wherein
an absorption terminal wavelength of the buffer layer is less than 380 nm.

3. The organic photoelectric conversion device according to claim 1, wherein
a hole mobility of the buffer layer is greater than or equal to a hole mobility of the organic photoelectric conversion layer.

4. The organic photoelectric conversion device according to claim 1, wherein
a conduction band of the metal oxide is lower, by 0.5 eV or more, than a LUMO level of the material having a glass transition temperature of 415K or more and having a property of blocking an exciton.

5. The organic photoelectric conversion device according to claim 1, wherein
the metal oxide includes at least one selected from the group consisting of molybdenum oxide, vanadium oxide, tungsten oxide, nickel oxide, and rhenium oxide.

6. An organic photoelectric conversion device comprising:
an organic photoelectric conversion layer;
a metal-oxide layer including a metal oxide; and
a buffer layer provided between the organic photoelectric conversion layer and the metal-oxide layer, the buffer layer including 4, 4′, 4″-Tri (9-carbazoyl) triphenylamine.

7. The organic photoelectric conversion device according to claim 6, wherein
a hole mobility of the buffer layer is greater than or equal to a hole mobility of the organic photoelectric conversion layer.

8. The organic photoelectric conversion device according to claim 6, wherein
a conduction band of the metal oxide is lower, by 0.5 eV or more, than a LUMO level of the 4, 4′, 4″-Tri (9-carbazoyl) triphenylamine.

9. The organic photoelectric conversion device according to claim 6, wherein
the metal oxide includes at least one selected from the group consisting of molybdenum oxide, vanadium oxide, tungsten oxide, nickel oxide, and rhenium oxide.
